(19) United States
(12) Patent Application Publication
(10) Pub. No.: US 2002/0068385 A1
(43) Pub. Date: Jun. 6, 2002

(54) Method for forming anchored bond pads in semiconductor devices and devices formed

(75) Inventors: Ssu-Pin Ma, Taipei (TW); Shyh-Chyi Wong, Taichung (TW); Chao-Chieh Tsai, Hsin-Chu (TW)

Correspondence Address: TUNG & ASSOCIATES, Suite 120, 838 W. Long Lake Road, Bloomfield Hills, MI, 48302, US

(73) Assignee: Taiwan Semiconductor Manufacturing Co., Ltd.

(21) Appl. No.: 09/727,833

(22) Filed: Dec. 1, 2000

(51) Int. Cl. H01L 21/44; H01L 21/48; H01L 21/50

(52) U.S. Cl. 438/118; 438/612

(57) ABSTRACT

A method for forming anchored bond pads on a semiconductor substrate and a semiconductor device containing such anchored bond pads are described. In the method, a plurality of via openings is first formed in a dielectric material layer on top of a semiconductor substrate. A metal is then filled into the plurality of via openings forming a plurality of via contacts and a bond pad on top of the dielectric material layer intimately connected to the plurality of via contacts. After the bond pad is defined by a photolithographic method, a bond pad that is anchored to the dielectric material layer by a plurality of via contacts is thus obtained. In an alternate embodiment, a first metal is used to form the plurality of via contacts, while a second metal is used to form the bond pad layer. A suitable first metal may be a refractory metal, while a suitable second metal may be aluminum or aluminum alloys. The first metal and the second metal may also be of the same material such as copper or a copper alloy.

### FIELD OF THE INVENTION

The present invention generally relates to a method for forming bond pads in a semiconductor device and more particularly, relates to a method for forming bond pads of a single metal layer anchored in a dielectric layer that do not have the bond pad liftoff defect.

### BACKGROUND OF THE INVENTION

In the fabrication of semiconductor devices, an integrated circuit chip is frequently assembled in a package during a final process step to complete the fabrication process. The package is then connected to a printed circuit board as part of a large circuit. To establish electrical communication with the integrated circuit chip, a wire bonding process can be used to connect a multiplicity of bond pads situated on the integrated circuit chip to the printed circuit board.

In a typical IC chip, active circuit elements such as transistors, resistors, etc., are formed in the central portion, i.e. the active region, of the chip while the bond pads are normally arranged around the periphery of the active region such that active circuit elements are less likely to be damaged during a subsequent bonding process. When a wire bonding process is performed on a bond pad on an IC chip, the process normally entails the bonding of a gold or aluminum wire to the bond pad by fusing the two together with ultrasonic energy. The wire is then pulled away from the bond pad after the bond is formed. During the bonding of the gold wire to the pad and the pulling away of the wire from the pad, high mechanical stress is placed on the bond pad. When the bond pads are not properly formed, defects such as delamination from the underlying substrate have been encountered. The delamination, or otherwise known as bond pad lift-off, occurs due to the fact that during the attachment process of a gold wire to a bond pad, a high level of mechanical stress is placed on the pad. It is also caused by the fact that a relatively large, heavy bond is placed on top of layers which may not have strong adhesion to the underlying layers. For instance, one factor that affects adhesion between the layers is the usage of a diffusion barrier layer formed of a material such as TiN for preventing aluminum diffusion into underlying conductive layers during subsequent high temperature processes. The diffusion barrier layer utilized, i.e., TiN, TiW or other alloys, does not have strong adhesion to the underlying oxide layer in the bond pad. This is one example of how the bond pad lift-off defect can occur.

Other processing parameters may also cause bond pad lift-off or delamination problem in semiconductor devices. For instance, low dielectric constant (low-k) materials have been used in recently developed semiconductor devices which causes adhesion problems between these low-k dielectric materials and the underlying oxide layers. The adhesion of these low-k dielectric materials, or inter-metal-dielectric (IMD) materials to oxide is poorer than that between oxide and oxide. The use of low-k dielectric materials, such as HSQ (hydrogen silsesquioxane) and MSQ (methylsil sesquioxane) is desirable in high performance semiconductor structures since thinner layers of the materials may be utilized as insulating layers due to their low-k characteristics. Another drawback of these low-k dielectric materials is their low thermal conductivity when compared to that of regular oxide. During a chip bonding process, the local temperature around a bond pad is significantly higher due to the poor thermal conductivity of the low-k dielectric material. The thermal stress caused by the poor thermal conductivity of IMD, in addition to the mechanical stresses caused by the bonding operation, may cause delamination of a low-k IMD layer from its underlying oxide layer.

In modern semiconductor devices that are designed specifically for high speed operation or for use in radio frequency circuits, it becomes highly desirable to use a single metal layer as the bond pad. The elimination of lower metal layers results in a smaller parasitic capacitance which is essential for such applications. In single metal layer bond pad applications, the bond pad lift-off defect becomes more severe due to poor adhesion of the single metal layer with the underlying dielectric layer. The single metal layer deposited on a dielectric layer no longer has the beneficial anchoring effect achieved in multiple metal layers. This is shown in FIGS. 1A, 1B and 1C.

FIG. 1A is an enlarged, cross-sectional view of a semiconductor device 10 formed with a bond pad 12 that has a multi-level metal structure. The bond pad 12 is constructed by four individual metal layers 14 connected therein between by a plurality of via contacts 16. The bond pad 12 is formed in a dielectric material layer 18 that is pre-deposited on a silicon substrate 20. The bond pad 12 is further covered along its edges by a passivation material layer 22.

As shown in FIG. 1A, the bond pad 12 is firmly anchored in the dielectric layer 18 by the multiple metal layers 14 which are interconnected by the plurality of via contacts 16. The adhesion between the bond pad 12 and the dielectric layer 18 is therefore strong such that it is suitable for conducting a wire pull test or a ball shear test, as shown in FIG. 1C.

On the other hand, in the single metal layer bond pad structure 24 shown in FIG. 1B for the semiconductor structure 30, the adhesion between the metal layer 26 and the dielectric layer 28, without any anchoring effect of the other metal layers or via contacts, is very weak and as a result, can not survive a wire pull bond test without delaminating from the dielectric layer 28. Furthermore, the single metal bond pad 24 may not survive a wire bonding process without the bond pad lift-off defect, as previously discussed.

It is therefore an object of the present invention to provide a method for forming bond pads of a single metal layer structure on a semiconductor substrate that does not have the drawbacks or shortcomings of the conventional bond pad forming methods.

It is another object of the present invention to provide a method for forming bond pads of a single metal layer structure on a semiconductor substrate by anchoring the single metal layer to an underlying dielectric layer.

It is a further object of the present invention to provide a method for forming anchored bond pads of a single metal layer structure on a semiconductor substrate by anchoring the bond pads to an underlying dielectric layer utilizing a plurality of via contacts.

It is still another object of the present invention to provide a method for forming anchored bond pads of a single metal layer structure on a semiconductor substrate by first forming a plurality of via contacts in a dielectric layer of a first metal and then forming a bond pad on top of the plurality of via contacts by a second metal.

It is still another object of the present invention to provide a method for forming anchored bond pads of a single metal layer structure on a semiconductor substrate by forming a plurality of via contacts in a dielectric layer and a single metal layer bond pad on top of the via contacts in the same metallization process.

It is yet another object of the present invention to provide a method for forming anchored bond pads of a single metal layer structure on a semiconductor substrate by first forming a plurality of via contacts and then forming a single layer metal bond pad on top in different metallic materials.

It is still another further object of the present invention to provide a semiconductor device that has metal bond pads anchored to an underlying dielectric layer which includes a plurality of via contacts formed of a first metal in the dielectric layer and a single metal layer bond pad formed of a second metal metallurgically connected to the plurality of via contacts.

It is yet another further object of the present invention to provide a semiconductor device that has metal bond pads anchored to an underlying dielectric layer in which a plurality of via contacts and a single metal layer bond pad formed on top are formed of the same metallic material.

### SUMMARY OF THE INVENTION

In accordance with the present invention, a method for forming anchored bond pads on a semiconductor substrate and a semiconductor device that has metal bond pads anchored to an underlying dielectric layer are provided.

In a preferred embodiment, a method for forming anchored bond pads on a semiconductor substrate can be carried out by the operating steps of providing a pre-processed semiconductor substrate, depositing a dielectric material layer on the substrate, forming a plurality of via openings in the dielectric material layer, filling the plurality of via openings and covering a top surface of the dielectric material layer with a first metal, and patterning and forming the layer of first metal into at least one bond pad.

The method for forming anchored bond pads on a semiconductor substrate may further include the steps of removing the first metal from the top surface of the dielectric material layer, depositing a layer of a second metal on the top surface of the dielectric material layer forming a bond with the first metal in the plurality of via openings, and patterning and forming the layer of second metal into at least one bond pad. The method may further include the step of depositing the dielectric material layer to a thickness between about 3,000 Å and about 25,0000 Å. The method may further include the step of forming the plurality of via openings by a photolithographic method, the step of selecting the first metal from the group consisting of refractory metals, or the step of selecting the second metal from the group consisting of aluminum and aluminum alloys. The method may further include the step of providing the first and the second metal in copper or copper alloys, or the step of forming the plurality of via openings to a depth between about 0.5 μm and about 2 μm, and to a width between about 0.1 μm and about 0.5 μm, or the step of forming the layer of first metal into at least one bond pad each connected to at least two vias formed in the plurality of via openings.

The present invention is further directed to a method for forming anchored bond pads in a semiconductor device which can be carried out by the operating steps of providing a pre-processed semiconductor substrate, depositing a dielectric material layer on the substrate, forming a plurality of via openings in the dielectric material layer, filling the plurality of via openings and covering a top surface of the dielectric material layer with a first metal, removing the first metal from the top surface of the dielectric material layer, depositing a layer of a second metal on the top surface of the dielectric material layer forming a bond with the first metal in the plurality of via openings, and patterning and forming the layer of second metal into at least one bond pad.

The method for forming anchored bond pads in a semiconductor device may further include the step of forming the plurality of via openings to a depth between about 0.5 μm and about 2 μm, and to a width between about 0.1 μm and about 0.5 μm. The method may further include the step of forming the at least one bond pad such that each bond pad is integrally connected to at least two via formed in the plurality of via openings. The method may further include the step of depositing the dielectric material layer to a thickness between about 3,000 Å and about 25,000 Å. The method may further include the step of selecting the first metal from the group consisting of refractory metals and selecting the second metal from the group consisting of aluminum and aluminum alloys. The method may further include the step of providing the first and second metals in copper or copper alloys.

The invention is still further directed to a semiconductor device that has metal bond pads anchored to an underlying dielectric material layer which includes a semiconductor substrate that has active circuits built thereon, a dielectric material layer overlying the semiconductor substrate, a plurality of vias formed of a first metal in the dielectric material layer, and at least one bond pad formed of a second metal on a top surface of the dielectric material layer each bonded to at least two of the vias.

In the semiconductor device that has metal bond pads anchored to an underlying dielectric material layer, the first metal may be a refractory metal and the second metal may be aluminum or aluminum alloys. The first metal and the second metal may be copper or copper alloys. The dielectric material layer may have a thickness between about 3,000 Å and about 25,000 Å. The plurality of vias may have a length between about 0.5 μm and about 2 μm and a width between about 0.1 μm and about 0.5 μm.

### BRIEF DESCRIPTION OF THE DRAWINGS

These and other objects, features and advantages of the present invention will become apparent from the following detailed description and the appended drawings in which:

FIG. 1A is an enlarged, cross-sectional view of a conventional semiconductor device having a bond pad formed on multiple layers of metal and a plurality of via contacts connected therein between.

FIG. 1B is an enlarged, cross-sectional view of a conventional semiconductor structure that has a bond pad formed of a single metal layer in a dielectric material layer.

FIG. 1C are graphs illustrating a wire pull and a ball shear test for a bond pad.

FIG. 2A is an enlarged, cross-sectional view of a present invention semiconductor structure having a bond pad anchored to a dielectric material layer by a plurality of via contacts.

FIG. 2B is a plane view of the bond pad in the present invention semiconductor structure of FIG. 2A.

FIG. 3A is an enlarged, cross-sectional view of a present invention semiconductor structure having a plurality of via openings formed in a dielectric material layer on top of a semiconductor substrate.

FIG. 3B is an enlarged, cross-sectional view of the present invention semiconductor structure of FIG. 3A with a first metal layer deposited on top.

FIG. 3C is an enlarged, cross-sectional view of the present invention semiconductor structure of FIG. 3B with the metal layer formed into a bond pad.

FIG. 4A is an enlarged, cross-sectional view of the present invention semiconductor structure with a plurality of via openings formed in a dielectric material layer on top of a semiconductor substrate.

FIG. 4B is an enlarged, cross-sectional view of the present invention semiconductor structure of FIG. 4A with a layer of a first metal deposited on top.

FIG. 4C is an enlarged, cross-sectional view of the present invention semiconductor structure of FIG. 4B with the first metal removed from the top surface of the dielectric material layer.

FIG. 4D is an enlarged, cross-sectional view of the present invention semiconductor structure of FIG. 4C with a layer of a second metal deposited on top.

FIG. 4E is an enlarged, cross-sectional view of the present invention semiconductor structure of FIG. 4D with the layer of the second metal formed into a bond pad connecting the via contacts formed of the first metal.

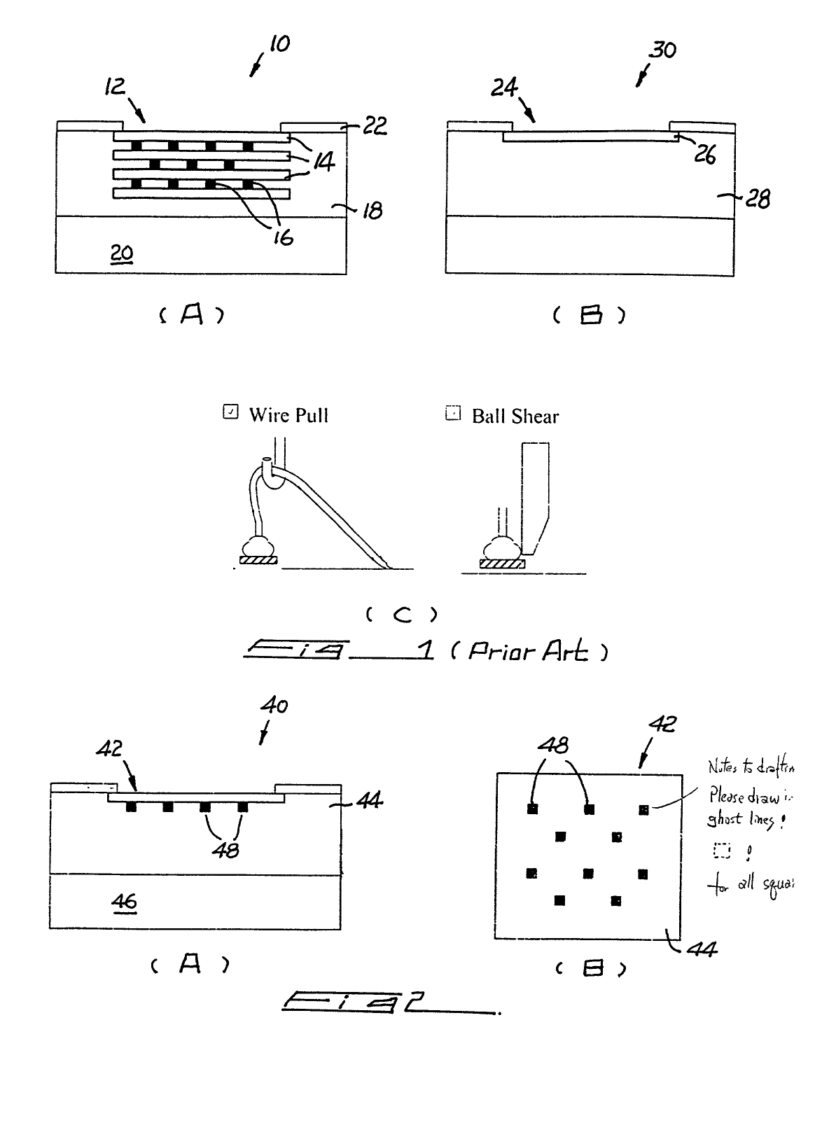

### DETAILED DESCRIPTION OF THE PREFERRED EMBODIMENT

The present invention discloses a method for forming anchored bond pads on a semiconductor substrate by first forming a plurality of via contacts in a dielectric material layer, and then forming a bond pad on top and integrally connected to the plurality of via contacts such that the bond pad is anchored to the dielectric material layer to prevent the occurrence of a bond pad lift-off defect.

In the present invention method, the plurality of via contacts may be formed of a first metal, while the bond pad layer may be formed of a second metal. The first metal may be a metal selected from the group of refractory metals, while the second metal may be selected from aluminum or aluminum alloys. The plurality of via contacts is formed in a dielectric material layer which may have a thickness between about 3,000 Å and about 25,000 Å, and preferably between about 5,000 Å and about 15,000 Å. The plurality of via openings for forming the via contacts may be formed by a photolithographic method.

In an alternate embodiment, the first metal and the second metal deposited are of the same material, i.e. copper or copper alloys, so that only one deposition process is required. A bond pad is formed of the metal layer on top of the dielectric material. The method can be more easily carried out since only one metal deposition process is required and furthermore, the removal of the first metal layer from the top of the dielectric material is not necessary.

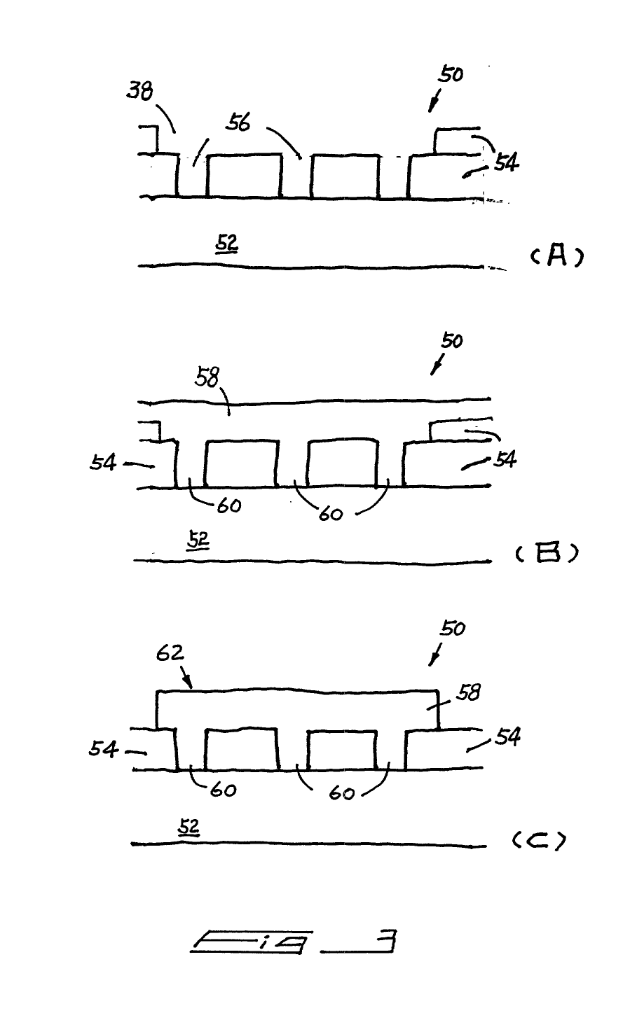

Referring now to FIG. 2A, wherein an enlarged, cross-sectional view of a present invention semiconductor structure 40 having a bond pad 42 formed in a dielectric material layer 44 is shown. The dielectric material layer 44 may be suitably formed of silicon oxide, BPSG (borophosphosilicate glass), PSG (phosphosilicate glass) or any other suitable insulating material. The dielectric material layer 44 is normally formed to a thickness between about 3,000 Å and about 25,000 Å, and preferably between about 5,000 Å and about 15,000 Å. The word “about” used in this specification indicates a range of value that is ±10% from the average value given. The dielectric material layer 44 is deposited on a silicon substrate 46.

As shown in FIG. 2A, the bond pad 42, which may be formed of aluminum, aluminum alloys, copper or copper alloys, on top of and integrally connected to a plurality of via contacts 48. The plurality of via contacts may be suitably formed of a refractory metal such as tungsten, titanium, etc.

FIG. 2B is a plane view of the semiconductor structure 40 illustrating a total of 10 via contacts are provided for the bond pad 42.

The plurality of via contacts 48 may be formed of a dimension of between about 0.5 μm and about 2 μm in length, and between about 0.1 μm and about 0.5 μm in width or in diameter. A more preferred range of the width (or diameter) is between about 0.2 μm and about 0.35 μm. A preferred dimension for the plurality of via contacts 48 is that the length is about 3˜4 times of the width.

The present invention novel method for forming anchored bond pads in a semiconductor device can be carried out in one of two embodiments. In the first embodiment, as shown in FIGS. 3A, 3B and 3C, a single metal material such as Cu or Cu alloy is utilized to form the via contacts and the bond pads in a dual damascene process.

Referring now to FIG. 3A, wherein a present invention semiconductor structure 50 is shown. The semiconductor structure 50 is formed by first providing a semiconductor substrate 52 of silicon material with integrated circuits formed(not shown) on top and then a thick layer of dielectric material 54 deposited to a thickness between about 3,000 Å and about 25,000 Å on top of the silicon substrate 52. The formation of the dielectric material layer 54, of silicon oxide, BPSG or PSG may be advantageously carried out by a chemical vapor deposition technique. After the dielectric material layer 54 is deposited, a plurality of via openings 56 may be formed by a standard photolithographic method. The via openings 56 are formed to a depth between about 0.5 μm and about 2 μm, and to a diameter between about 0.1 μm and about 0.5 μm. After the formation of via openings 56, trench openings 38 is formed by lithography and etching in the same dielectric material layer 54.

In the next step of the process, as shown in FIG. 3B, a metal layer 58 is sputter deposited on top of the semiconductor structure 50 so that it fills the plurality of via openings 56 and trench opening 38 and forms a plurality of via plugs 60. After a chemical mechanical polishing process is conducted, bond pad 62 is patterned and formed of the metal layer 58. This is shown in FIG. 3C. The bond pad 62 is integrally connected to the plurality of via contacts 60 and forms a firm anchor into the dielectric material layer 54. The anchored bond pad 62 formed by the present invention novel method has significantly increased bond strength to the dielectric material layer 54 and thus, defects such as bond pad lift-off or delamination can be avoided.

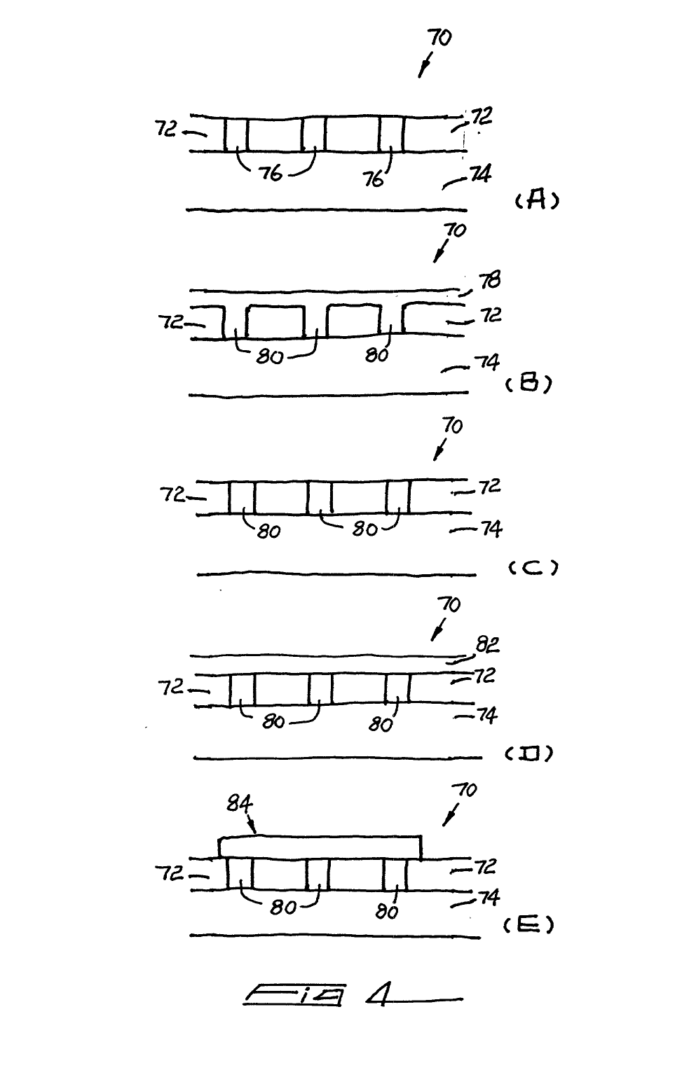

In a second embodiment of the present invention novel method, as shown in FIGS. 4A-4E, different metal layers are deposited to form the plurality of via contacts and the bond pad, respectively. It should be noted that either different materials or the same material may be used for the first and the second metal layer.

Referring to FIG. 4A, wherein an enlarged, cross-sectional view of the present invention semiconductor structure 70 is shown. The semiconductor structure 70 is first formed by depositing a dielectric material layer 72 on top of a silicon substrate 74. A plurality of via openings 76 is then formed by a standard photolithographic method in the dielectric material layer 72. The dielectric material layer 72 may be suitably formed of a material such as silicon oxide, PSG or BPSG. The dimensions of the plurality of via openings 76 may be similar to those previously described in the first embodiment.

As shown in FIG. 4B, a first metal material 78 is then deposited on top of the semiconductor structure 70 filling the plurality of via openings 76 and covering a top surface of the dielectric material layer 72. The plurality of via openings 76 is filled with the first metal 78 to form a plurality of via contacts 80. The first metal material may be suitably a refractory metal, i.e. tungsten or titanium, to advantageously fill the via openings 76 by a chemical vapor deposition technique. For instance, tungsten CVD is especially suitable for filling of via openings that have high aspect ratios such as 4:1.

The first metal material 78 on top of the dielectric material layer 72 is then removed either by a chemical mechanical polishing method or by an etching technique. This is shown in FIG. 4C with only the plurality of via contacts 80 left in the dielectric material layer 72.

In the next step of the process, as shown in FIG. 4D, a second metal material 82 is deposited on top of the semiconductor structure 70 and bonded to the plurality of via contacts 8O. A suitable material for the second metal 82 may be aluminum, aluminum alloys, copper or copper alloys.

In the final step of the process, as shown in FIG. 4E, a standard photolithographic method is used to pattern and form the bond pad 84 from the second metal layer 82. The process, while requiring a separate removal step for the first metal and a separate deposition step for the second metal, may be advantageously used to select a metal for forming the via contacts and a metal for forming the bond pad to facilitate a subsequent bonding process. The first metal and the second metal selected should have good bonding characteristics in order to form an intimate bond between the bond pad 84 and the plurality of via contacts 80. An anchored bond pad that has superior bond pad lift-off resistance can be formed by the second embodiment of the present invention novel method.

The present invention novel method for forming anchored bond pads on a semiconductor substrate by utilizing a plurality of via contacts connected to the bond pad for anchoring to a dielectric material layer and a semiconductor device thus formed have therefore been amply described in the above description and in the appended drawings of FIGS. 2A˜4E.

While the present invention has been described in an illustrative manner, it should be understood that the terminology used is intended to be in a nature of words of description rather than of limitation.

Furthermore, while the present invention has been described in terms of a preferred and an alternate embodiment, it is to be appreciated that those skilled in the art will readily apply these teachings to other possible variations of the inventions.

The embodiment of the invention in which an exclusive property or privilege is claimed are defined as follows.

1. A method for forming anchored bond pads on a semiconductor substrate comprising the step of:
providing a pre-processed semiconductor substrate;
depositing a dielectric material layer on said substrate;
forming a plurality of via openings in said dielectric material layer;
filling said plurality of via openings and covering a top surface of said dielectric material layer with a first metal; and
patterning and forming said layer of first metal into at least one bond pad.

2. A method for forming anchored bond pads on a semiconductor substrate according to claim 1 further comprising the step of:
removing said first metal from said top surface of said dielectric material layer;
depositing a layer of a second metal on said top surface of said dielectric material layer forming a bond with said first metal in said plurality of via openings; and
patterning and forming said layer of second metal into at least one bond pad.

3. A method for forming anchored bond pads on a semiconductor substrate according to claim 1 further comprising the step of depositing said dielectric material layer to a thickness between about 3,000 Å and about 25,000 Å.

4. A method for forming anchored bond pads on a semiconductor substrate according to claim 1 further comprising the step of forming said plurality of via openings by a photolithographic method.

5. A method for forming anchored bond pads on a semiconductor substrate according to claim 1 further comprising the step of selecting said first metal from the group consisting of refractory metals.

6. A method for forming anchored bond pads on a semiconductor substrate according to claim 1 further comprising the step of selecting said second metal from the group consisting of aluminum and aluminum alloys.

7. A method for forming anchored bond pads on a semiconductor substrate according to claim 1 further comprising the step of providing both said first and said second metal in copper or copper alloys.

8. A method for forming anchored bond pads on a semiconductor substrate according to claim 1 further comprising the step of forming said plurality of via openings to a depth between about 0.5 μm and about 2 μm, and to a width between about 0.1 μm and about 0.5 μm.

9. A method for forming anchored bond pads on a semiconductor substrate according to claim 1 further comprising the step of forming said layer of first metal into at least one bond pad each connected to at least two vias formed in said plurality of via openings.

10. A method for forming anchored bond pads in a semiconductor device comprising the step of:
providing a pre-processed semiconductor substrate;
depositing a dielectric material layer on said substrate;
forming a plurality of via openings in said dielectric material layer;
filling said plurality of via openings and covering a top surface of said dielectric material layer with a first metal;
removing said first metal from said top surface of said dielectric material layer;
depositing a layer of a second metal on said top surface of said dielectric material layer forming a bond with said first metal in said plurality of via openings; and
patterning and forming said layer of second metal into at least one bond pad.

11. A method for forming anchored bond pads in a semiconductor device according to claim 10 further comprising the step of forming said plurality of via openings to a depth between about 0.5 μm and about 2 μm, and to a width between about 0.1 μm and about 0.5 μm.

12. A method for forming anchored bond pads in a semiconductor device according to claim 10 further comprising the step of forming said at least one bond pad such that each bond pad is integrally connected to at least two vias formed in said plurality of via openings.

13. A method for forming anchored bond pads in a semiconductor device according to claim 10 further comprising the step of depositing said dielectric material layer to a thickness between about 3,000 Å and about 25,000 Å.

14. A method for forming anchored bond pads in a semiconductor device according to claim 10 further comprising the step of selecting said first metal from the group consisting of refractory metals and selecting said second metal from the group consisting of aluminum and aluminum alloys.

15. A method for forming anchored bond pads in a semiconductor device according to claim 10 further comprising the step of providing both said first and said second metal in copper or copper alloys.

16. A semiconductor device having metal bond pads anchored to an underlying dielectric layer comprising:
a semiconductor substrate;
a dielectric material layer overlying said semiconductor substrate;
a plurality of vias formed of a first metal in said dielectric material layer; and
at least one bond pad formed of a second metal on a top surface of said dielectric material layer each bonded to at least two of said vias.

17. A semiconductor device having metal bond pads anchored to an underlying dielectric layer according to claim 16, wherein said first metal is a refractory metal and said second metal is aluminum or aluminum alloys.

18. A semiconductor device having metal bond pads anchored to an underlying dielectric layer according to claim 16, wherein said first metal and said second metal are copper.

19. A semiconductor device having metal bond pads anchored to an underlying dielectric layer according to claim 16, to wherein said dielectric material layer has a thickness between about 3,000 Å and about 25,000 Å.

20. A semiconductor device having metal bond pads anchored to an underlying dielectric layer according to claim 16, wherein said plurality of vias has a length between about 0.5 μm and about 2 μm and a width between about 0.1 μm and about 0.5 μm.
